(19) United States
(12) Patent Application Publication
(10) Pub. No.: US 2010/0151680 A1
(43) Pub. Date: Jun. 17, 2010

(54) Substrate carrier with enhanced temperature uniformity

(75) Inventors: Shulin Wang, Campbell, CA (US); Gautam Ganguly, San Ramon, CA (US); Marvin Keshner, Sonora, CA (US); Erik G. Vaaler, Redwood City, CA (US); James Harroun, Concord, CA (US); Paul McClelland, Monmouth, OR (US)

Correspondence Address: THE NATH LAW GROUP, 112 South West Street, Alexandria, VA, 22314, US

(73) Assignee: OPTISOLAR INC., Hayward, CA (US)

(21) Appl. No.: 12/314,809

(22) Filed: Dec. 17, 2008

(51) Int. Cl. H01L 21/3205; H01L 21/67

(52) U.S. Cl. 438/680; 118/723 VE; 257/E21.295

(57) ABSTRACT

A substrate carrier is used in an in-line fabrication such as Plasma Enhanced Chemical Vapor Deposition (PECVD) for application of thin film on substrates. The carrier is in thermal communication with the substrate and thereby provides heat sinking. The carrier further permits movement of the substrate past a deposition apparatus at a deposition station.

### FIELD

This disclosure relates to the fabrication of semiconductors. More particularly, the disclosure relates to the use of plasma processes in the fabrication of thin film devices, such as photovoltaic solarcells, in a continuous process.

### BACKGROUND

For the vacuum deposition of many materials, the uniformity of temperature across the substrate on which the materials are deposited is a critical parameter. In many prior art systems, the substrates are stationary during deposition and held in intimate contact with a metal chuck. The metal chuck is often made of a thick plate of aluminum or another metal with a very high thermal conductivity. The thickness of the plate and the high thermal conductivity promote temperature uniformity across the surface of the plate. The intimate contact of the substrate to the plate creates excellent heat transfer between the plate and the substrate. Therefore, the temperature at every location on the surface of the substrate will be very close to the temperature on the surface of the metal plate. Thus, if the plate has a uniform temperature across its surface, then the substrate will also have a uniform temperature across its surface.

In plasma processing of materials, the metal plate is often cooled or heated to maintain it at the desired temperature during the deposition process. The plate is machined to be very flat. The substrate is held in intimate contact with the plate by either a vacuum created through small holes in the plate or by an electrostatic charge between the plate and the substrate.

In the manufacture of thin film photovoltaic arrays, thin film photovoltaic panels are formed by forming glass sheets, which optionally are provided with an initial coating. The sheets are then annealed and tempered. Active semiconductor layers are coated onto the glass sheets over the initial coating. This can be accomplished using plasma enhanced chemical vapor deposition (PECVD). The PECVD is performed in a vacuum chamber, in which radio frequency is used to energize precursor gases (e.g., silane) supplied to the vacuum chamber. The radio frequency turns the precursor gases into a plasma, resulting in the chemical vapor deposition of the semiconductor material. Subsequently, additional coatings may be applied.

One issue with Plasma Enhanced Chemical Vapor Deposition (PECVD) is the generation of heat, resulting in a variation of temperature across the substrate. In particular, with thin film substrates, such as those often used to produce photovoltaic solarcells, it is desired to continuously transport the substrate through a PECVD station so that the entire working surface formed on the substrate is passed under a PECVD showerhead. This combines the need for transport with a need for intense exposure of the entire working surface to PECVD, and results in considerable heat absorption and consequent increases in temperature of the substrate. The heating of the substrate from the PECVD source is often not uniform. Therefore, it is desirable to have some means by which the substrate is maintained at a uniform temperature across its entire surface.

In many other prior art vacuum deposition systems, the substrates are not stationary. Instead, they are moved past a stationary deposition source, such as a sputtering source, CVD source or a PE-CVD source. In some cases, the substrates are held onto a rotating metal plate and the metal plate with substrate attached is rotated past the deposition source. In other prior art cases, the substrate is moved continuously in a linear motion past a deposition source. In some of the prior art systems with linear motion, the substrate, such as glass, is moved on rollers and not held against any form of plate. In other prior art systems, the substrate is first mounted into a metal frame and then the combination of metal frame and substrate is moved on rollers past the deposition source. FIG. 1 depicts such a system, taken from an end view. A deposition source 101 is provided within a vacuum chamber (not depicted) and a substrate 103 is moved past the deposition source 101. A heater 105 is used to establish a preferred temperature of the substrate 103 for performing the work. While the initial temperature of the substrate 103 can be controlled by the heater, the plasma deposition process itself generates heat which is also transferred to the substrate 103. The substrate temperature is the result of the heat that flows from the plasma deposition process plus the heat that flows to or from the heater.

Any motion of the substrate makes it much more difficult to control the temperature of the substrate. In a typical prior art system with linear motion, the substrate is moved between a heater that heats the back surface and the deposition source that deposits material on the front surface (of the substrate). The heater often includes a thick plate of thermally conductive material, such as aluminum or graphite, so that the heater temperature will be uniform across its surface. The heater is not in contact with the substrate. Heat is transferred from the heater to the substrate partially by black-body radiation and partly by conduction through the low pressure gas in the vacuum chamber. At very low pressures, less than a few millitorr, the heat transfer is almost entirely by radiation. Above about 0.3 torr, heat transfer through the gas is also significant, particularly if the gas is hydrogen or helium, rather than argon, nitrogen or oxygen.

Movable chucks for PECVD are known; however these chucks are generally unrelated to a carrier back plate structure or of an in-line silicon process. Similarly, there are heat sinks used as back plates in photovoltaic cells, such as heat sinked printed circuit board materials, but for purposes unrelated to PECVD.

The substrate often also receives heat on its front surface from the deposition source. For example, for a magnetron sputtering system, the deposition tends to be highly concentrated over a distance of less than 10 cm. The heat from the deposition source is also concentrated over a small distance, often much smaller than the dimensions of the substrate.

The heater behind the substrate is a heat source with a very uniform temperature across it surface. In contrast, the deposition source in front of the substrate is also a heat source that is very non-uniform compared with the dimensions of the substrate. If the heat flow from the deposition source is small, then good temperature uniformity can be achieved. But, if the heat flow from the deposition source is comparable in strength to the heat flow by radiation and by conduction from the heater to the substrate, then the substrate temperature will not be uniform.

### SUMMARY

Fabrication of thin film semiconductor devices is achieved by mounting a substrate against a back plate, with the substrate juxtaposed against the back plate. The back plate is transported, with the substrate, through a deposition chamber and exposed to a deposition process. Heating or cooling of the substrate occurs through the back plate during the deposition process, so as to provide temperature uniformity during a deposition process.

### BRIEF DESCRIPTION OF THE DRAWINGS

FIG. 1 (prior art) is a diagram depicting movement of a substrate through a moving deposition chamber in a thin film photovoltaic fabrication process.

FIGS. 2A and 2B are end and top views, respectively, depicting the use of a carrier and back plate used to move a substrate through a moving deposition chamber in a thin film photovoltaic fabrication process.

FIG. 3 is a diagram showing the configuration of an in-line thin film fabrication process employing a Plasma Enhanced Chemical Vapor Deposition (PECVD) station.

FIGS. 4A and 4B are diagrams showing the use of a clamshell assembly with a pre-bowed substrate to assure intimate contact between the substrate and a back plate. FIG. 4A depicts the pre-bowed substrate, and FIG. 4A depicts the substrate after clamping pressure is applied by the back plate.

FIG. 5 is a diagram showing the use of a vacuum to hold the substrate against the back plate and pockets in the back plate to store vacuum in order to assure intimate contact between the substrate and a back plate.

FIG. 6 is a diagram showing the use of a high voltage to hold the substrate against the back plate, in order to assure intimate contact between the substrate and a back plate, and a high voltage insulator between the carrier and back plate.

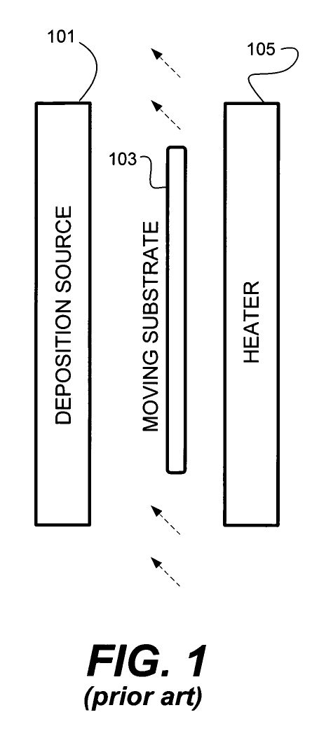

### DETAILED DESCRIPTION

Overview

Glass substrates are widely used in the LCD and solar cells industry. Silicon (Si), one of the key elements of the active circuitry, is typically deposited by plasma enhanced chemical vapor deposition (PECVD). Measurements show that the substrate temperature keeps increasing after being exposed to the plasma; however, it is preferred that the substrate temperature should be constant during plasma enhanced Si deposition.

In an in-line Si deposition process, the glass substrate moves continually from one process chamber to the next one. According to this disclosure, a transparent conducting oxide (TCO) glass substrate is mounted in the metal frame carrier used in some of the Si deposition chambers. A carrier and back plate are used to move the substrate through a moving deposition chamber in a thin film photovoltaic fabrication process.

According to one aspect, a substrate is mounted in a vacuum deposition system. The substrate is held between a carrier frame and a back plate so that the entire assembly can be moved linearly past a deposition source. The carrier frame may be constructed of metal or ceramic. Likewise, the carrier frame and the back plate may be constructed of metal or ceramic.

General Configuration

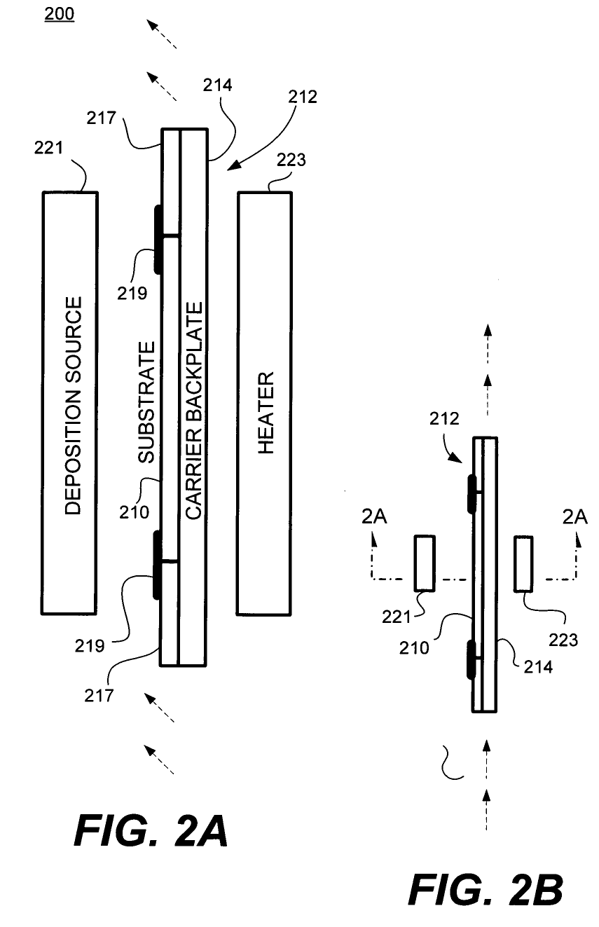

FIGS. 2A and 2B are diagrams of a deposition chamber 200 showing substrate 210 supported by a carrier 212 with a heat spreading plate 214. The heat spreading plate 214 is a thermally conductive plate is placed in contact with the bottom of the substrate 210 to spread the plasma-generated heat and make the substrate temperature more uniform over the substrate area. The thermal mass of the carrier and back plate also makes the substrate temperature more stable over time and prevents large changes in temperature when the substrate moves directly in front of the deposition source and receives the heat from the deposition source. The thermally conductive plate 214 can be mounted on the carrier 212 or be part of the carrier. The back plate can be aluminum, copper, alumina or any material having good thermal conductance.

In FIG. 2A, the depiction is in a top view, in which the carrier 212 and back plate 214 move the substrate 210 through a moving deposition chamber 200 in a thin film photovoltaic fabrication process. The carrier includes a carrier frame 217, back plate 214 and one or more substrate retention inserts 219. The substrate 210 is supported by carrier frame 217, and is held between back plate 214 and retention inserts 219. In one example, retention inserts 219 are made of a material that more closely matches the thermal expansion coefficient of the substrate, one particular example being titanium.

The carrier 212 is supported by rollers (not shown) which provide electrical grounding and move the carrier 212 forward.

A deposition source, which in the case of PECVD is a plasma head 221 is provided. Plasma head 221 is configured to extend across the glass transverse to the movement of the glass within the chamber. A heater 223 is used to establish a desired starting temperature. The movement of carrier 212 is linear past the plasma head 221, with the arrows in FIG. 2A intended to depict such movement in a manner such that the distance between plasma head 221 and the plane of the carrier 212 does not change. FIG. 2B is a top view, in which the movement through the chamber 200 is as depicted by the arrows.

The substrate carrier 212 has heat sink characteristics and is used to transport the substrate 210 to be moved continually from one process chamber to another process station. The heat sink characteristics are particularly useful for performing a PECVD step. The transport mechanism is used to position the carrier 212 and substrate 210 in a substantially vertical alignment, and transports the carrier and substrate in a substantially horizontal direction within the deposition chamber past a deposition head.

The configuration is of a heat spreading back plate mounted in a carrier behind a glass substrate. The plate is used in an in-line silicon processes in which the carrier is supported by rollers which provide electrical grounding and move the carrier forward.

Temperature is controlled by heater 223 and by back plate 214. This results in uniformity of the temperature of a large substrate in a vacuum deposition system with continuous motion of the substrate in a linear direction. Prior to the PECVD processing, substrate 210 is first mounted into carrier frame 212. This can be done at the beginning of processing or at a later point in the processing, such as before a particular PECVD process in which heat spreading is desired. For a glass or silicon substrate, since most materials with high thermal conductivity also have large coefficients of thermal expansion, retention inserts 219 may be made with a material that has similar coefficients of thermal expansion. By way of non-limiting example, a suitable material for glass substrates would include titanium.

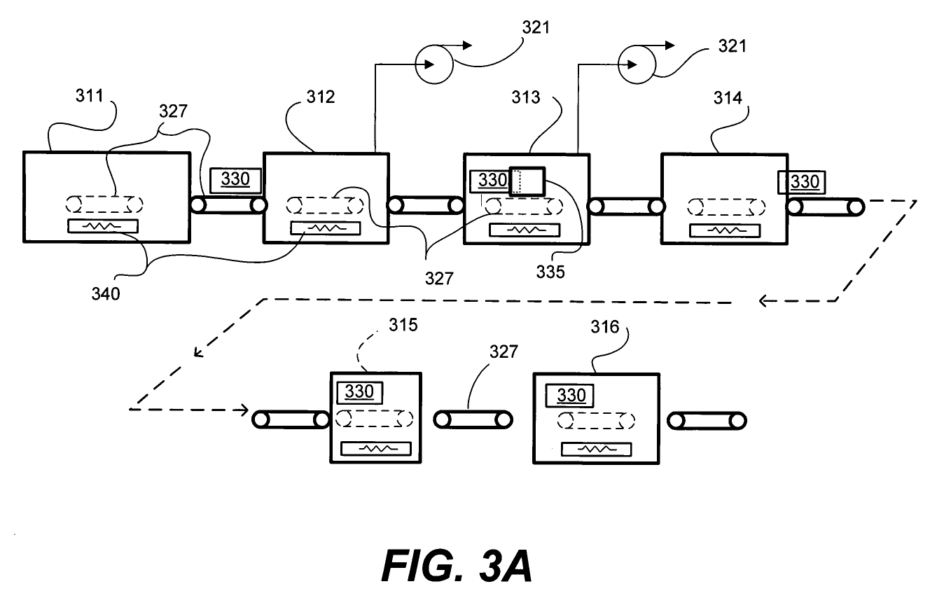

Carrier 212 is used in an in-line deposition configured for continuous in-line thin film fabrication. FIG. 3 is a diagram showing the configuration of an in-line thin film fabrication process employing a Plasma Enhanced Chemical Vapor Deposition (PECVD) station. Depicted are plural stations 311-316. One or more of the stations, such as stations 312, 313 are used for plasma deposition processes, such as PECVD, and employ vacuum operation as represented by vacuum pumps 321. While separate vacuum pumps 321 are depicted for separate stations, it is possible to provide a common vacuum chamber for multiple ones of the stations 311-316.

Carriers 330 onto which substrates are mounted, are transported into deposition chamber 313 and a vacuum is drawn in order to facilitate the PECVD process. Heaters 340 are positioned in each chamber to maintain the temperature of the carrier and substrate. PECVD head 335 is positioned in the chamber 313 and carrier 330 with the substrate (not separately shown) is moved past PECVD head 335, where materials such as polysilicon, amorphous silicon or microcrystalline silicon are deposited on the substrate.

Referring again to FIGS. 2A and 2B, back plate 214 is thermally conductive and spreads the heat generated by the plasma to create a uniform temperature across the substrate. This keeps substrate temperature stable over time and uniform across the substrate during the PECVD deposition. Referring again to FIG. 3, the moving carrier is compatible with multi-chamber system, in which the carrier 330 with substrates travel on rollers represented by conveyers 327 from chamber to chamber 311-316.

Pre-Bowed Substrate

For a substrate that is bowed or warped in one direction towards the carrier and away from the deposition source, the substrate can be flattened against the back plate of the carrier when the glass substrate is installed into the carrier. Tempered glass is often bowed or warped. Also, the tempering process can be controlled to produce a substrate with a pre-bow or pre-warp that is always in one direction

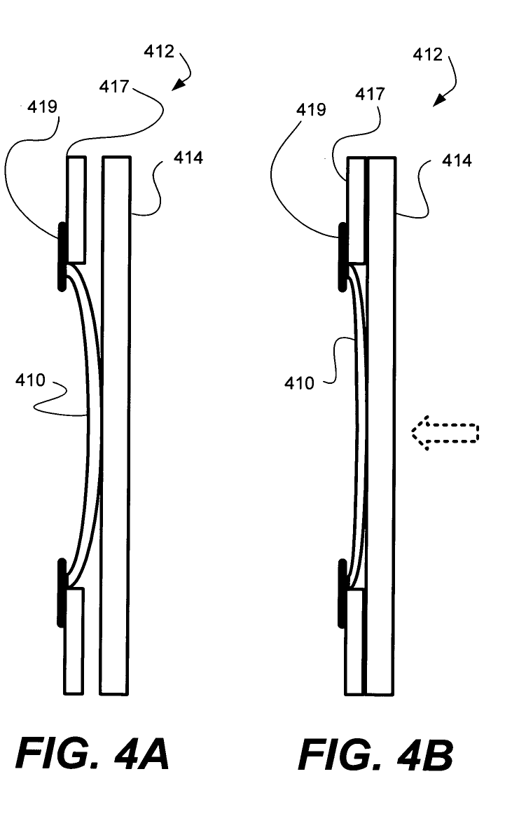

FIGS. 4A and 4B are diagrams showing an arrangement in which a pre-bowed substrate 410 is engaged by a carrier 412 with a back plate 414 and carrier frame 417. Carrier 412 is configured to cause back plate 414 to press against the substrate 410. The configuration uses a clamshell assembly with the pre-bowed substrate 410 to assure intimate contact between the substrate 410 and the back plate 414. FIG. 4A depicts the pre-bowed substrate 410, and FIG. 4A depicts substrate 410 after clamping pressure is applied by back plate 414.

One or more retention inserts 419 are fastened onto carrier frame 417 in a manner to permit retention inserts 419 to bend a little to apply force to hold substrate 410. The retention insert material is made to be relatively thin compared with substrate 410 and carrier frame 417, so that the force applied to substrate 410 is not too great and will not crack or break substrate 410. Finally, back plate 414 may be made of the same material as carrier frame 417 and is mounted behind the substrate and fastened to the carrier frame. The back plate is made relatively thick and highly thermally conductive. The back plate easily conducts heat laterally and forces the substrate temperature to be uniform in the lateral directions. In addition, the back plate is made thick enough and strong enough so that the substrate can be pressed flat against the back plate to remove any bowing or warping of the substrate prior to mounting. The overall effect is a clamshell-like design in which the glass is held in the center of two pieces of materials. At least one of them, usually the back plate has a high thermal conductivity.

The back plate holds the substrate against the retention insert material. The back of the substrate sees only the surface of the back plate. Most of the front of the substrate is exposed so that it can receive deposition from a vacuum deposition source. The retention insert material holds the substrate by its edges and shields the edges from the vacuum deposition source. The retention insert material applies enough force to hold the substrate, and in the event that the substrate is bowed or warped, enough additional force to partially flatten the substrate against the back plate.

In the event that the substrate is bowed outward away from the back plate, then the retention inserts will hold the edges of the substrate flat against the back plate, but the center of the substrate will still bow outward away from the back plate and toward the deposition source. To avoid this, the substrate is intentionally processed so that is slightly bowed away from the surface on which the deposition is to occur. Then, with pressure from the retention insert along the edges of the substrate, and with pressure from the back plate, the initial inward bow will be pressed flat against the back plate.

One aspect of the disclosure involves holding the substrate in intimate contact with the back plate while restraining the substrate against the back plate. It is the back plate, its thickness and high thermal conductivity that assure good temperature uniformity. If the substrate is even a fraction of a millimeter away from the back plate, the heat conduction from the back plate to the substrate will be greatly diminished. In such circumstances, the heat from the deposition source that is hitting the front surface will be able to create significant temperature non-uniformity across the surface of the substrate.

Processing the substrate creates a small bow in the direction of the back plate. This can be accomplished by heating the glass and cooling it more quickly on one side than the other. For a glass substrate, this often happens in the process of making tempered glass. The direction of the bow can be easily controlled by regulating the air flow during the cooling process. For silicon substrates, one could grind the substrate so that it has a bow in the desired direction.

Vacuum Support of Substrate

It may also be necessary to use glass substrates that are not controlled during the tempering process and that can be bowed or warped in either direction. When the glass is bowed outward toward the deposition source, the process of installing it into the carrier will not flatten the bow or warp in the center of the substrate. For these substrates, vacuum or an electrostatic force may be used to pull the center of the substrate toward the back plate. Depending on the degree of bowing or warping, more or less force must be supplied by the vacuum or electrostatic charge to both hold the glass onto the metal plate and flatten it against the metal plate.

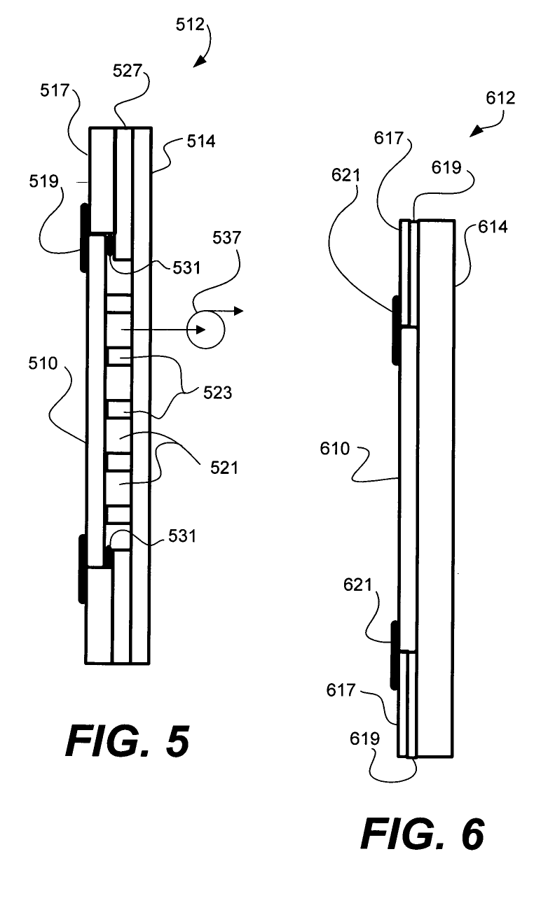

FIG. 5 is a diagram showing the use of a vacuum to hold the substrate 510 in a carrier 512 against the back plate 514. A carrier frame 517 is positioned at the perimeter of the substrate 510, and forward of the back plate 514. A plurality of pockets 521 are located between the substrate 510 and the back plate and are established between ribs 523 formed on the back plate 514. A perimeter spacer 527 is located at a perimeter region adjacent the pockets 521 and ribs 523, with some overlap at the outer edge of the substrate 510. Perimeter spacer 527 and ribs 523 may be formed integrally with back plate 514, or may be assembled as separate component parts.

An elastomeric seal or O-ring 531 is provided between the substrate 510 and the spacer 527 at the overlap location. O-ring 531 forms a seal between the perimeter spacer 527 and substrate 510 and allows for a lower pressure behind the substrate compared with the gas pressure in the deposition chamber.

Pockets 521 in the back plate 514 function to store vacuum in order to assure intimate contact between the substrate 510 and a back plate 514. A vacuum is established between the substrate 510 and the back plate 514 to assure intimate contact between the two at ribs 523. The PECVD chamber is normally pumped down to an operating pressure that is typically set somewhere in the range between 0.1 and 10 torr. A lower pressure (more vacuum) is applied between the back plate 514 and the substrate 510 in order to achieve a significant differential pressure between the back plate 514 and the substrate 510. By way of non-limiting example, the vacuum applied to attract the back plate 514 to the substrate 510 is a partial pressure of 0.25 that of the PECVD chamber.

The vacuum behind the substrate 510 can be drawn by a pump 537, which may be a separate pump, from that used to draw a vacuum in the PECVD chamber as a whole. Alternatively, a vacuum pump used for the PECVD chamber can also be used to draw a vacuum behind the substrate 510. In general, PECVD chambers use a throttle valve in the connection to the vacuum pump, and so it is possible to connect the back plate 514 upstream of the throttle valve to the vacuum pump (on the vacuum pump side of the throttle valve). The back plate 514 can be provided with a separate throttle valve or connected without a throttle valve.

As one way of maintaining the vacuum between the substrate 510 and back plate 514, a seal at the edges of the substrate 510 is formed, for example with O-ring 531, and a vacuum is pulled between the substrate 510 and back plate 514. Either the O-ring 531 seals would be so tight that the vacuum would hold throughout the deposition process (often many 100's of seconds), or the back plate 514 is reconnected during the deposition with a vacuum connection to evacuate any gas that may have leaked into the space between the back plate 514 and the substrate 510. The back plate 514 would have ridges and valleys so that the substrate 510 would be supported by the ridges and the valleys would provide the volume for the vacuum. The area of the ridges would have to be sufficient to maintain good thermal contact and the spacing between ridges close enough to avoid significant thermal gradients. For example, with an aluminum back plate 514, one could use 2 mm ridges on 1 cm centers or 2 mm×2 mm posts on 1 cm centers in both directions.

One or more retention inserts 519 may optionally be used to retain the substrate 510, or the substrate 510 may be retained by the carrier 512 without the inserts.

In an example configuration, the back plate 514 faces the back of the substrate 510 in a grid arrangement. A plurality of openings are arranged between ribs 523, such that the ribs are arranged on a 1 cm spacing. Each rib 523 is 2 mm wide, resulting in an 8 mm gap between ribs. In this example, the contact interface of approximately 20% of the back of the substrate 510 is sufficient for heat sinking and heat spreading. It is, however, possible to provide a denser interface, for example 50% or 80% of the back surface of the substrate 510. Conversely, it is possible to provide a lesser contact interface, such as 10%, 5% or 2% of the contact interface. Similarly, it is possible to configure the back plate 514 differently, such as honeycomb, drilled plate or with any other convenient configuration.

It is noted that, since the PECVD chamber must have vacuum applied in order to function properly, the back plate 514 itself can be fairly leaky in its seal with the substrate 510. The leakage can be up to the pump down rate of the PECVD chamber without significantly affecting the operation of the PECVD chamber because the vacuum leakage would be within the chamber.

Electrostatic Attraction

FIG. 6 is a diagram showing the use of a high voltage to hold substrate 610 in a carrier 612 against a back plate 614 by use of electrostatic attraction between substrate 610 and back plate 614. A carrier frame 617 is positioned at the perimeter of substrate 610, and forward of back plate 614. An insulating spacer 619 separates carrier frame 617 and back plate 614. Insulating spacer 619 performs as a high voltage insulator.

One or more retention inserts 621 may optionally be used to retain the substrate 610, or the substrate 610 may be retained by the carrier 612 without the inserts.

After the substrate is mounted in the carrier, a large EMF (voltage) is applied between the substrate 610 and back plate 614. The EMF attracts the glass to the back plate, flattens the glass substrate and is used to hold the substrate 610 and back plate 614 in intimate contact via electrostatic force. In some cases, the EMF can be applied once at the beginning of the deposition process and then released at the end of the deposition process. In other cases, the leakage current between the front of the substrate (at ground potential) and the back plate (with a large EMF) may be too great and the EMF may decrease with time. In these cases, the EMF can be applied continuously during the deposition process by an electrically conductive wiper in each chamber that is repeatedly in contact with the back plate and restores the EMF to its full value.

If the substrate is glass and a good electrical insulator, then no additional insulator beyond the insulating separator at the periphery (619) is required. On the other hand, for a conductive substrate, such as a silicon wafer, an additional insulator is required. In this configuration, a thin insulator (not separately depicted) is provided on the surface of the back plate that faces the substrate or alternatively on the back surface of the carrier that faces the back plate. This insulating layer is made with a material that is both a good electrical insulator and preferably also has a high value of thermal conductivity. A non-limiting example of such a material is aluminum oxide. For an insulating substrate such as glass, the top surface of the substrate 610, the carrier frame 617 and the retention inserts 621 would be at ground potential, while the back plate would be at a high voltage, sufficient to pull the substrate 610 strongly against the surface of the back plate. In the event of a glass substrate or other insulating substrate, the front surface of the substrate 610 that faces away from the carrier and toward the deposition source would be conductive and in contact with the retention insert metal. Both the front, conductive surface of the glass substrate and the retention insert metal would be held at ground potential. The back surface of the glass that faces away from the deposition source and will be in intimate contact with the back plate can be insulating or coated with a conductive material, provided that the back and front surfaces are insulated from each other by the thickness of the glass and by the edges of the glass.

For a conducting substrate, the thin insulator would cover the entire surface of the back plate 614. The substrate 610, carrier frame 617 and retention inserts 621 would be at ground potential and the back plate 614 would be at a high voltage, sufficient to pull the substrate strongly against the insulating spacer 619, which is supported by the back plate 614. The charge on the back plate 614 may be maintained by an electrical brush or wiper that was continuously in contact with the back plate 614 as the substrate 610, carrier frame 617, retention inserts 621 and back plate 614 assembly move through the vacuum deposition system. In order to accommodate a large voltage applied to the back plate 614, the rollers that move the assembly would be insulating and capable of withstanding the high voltage.

The electrostatic charge is applied to the back of the substrate 610 only. The forward part of the substrate is typically at ground potential during the PECVD process. Initially, when the substrate is bowed a large distance from the back plate, a large voltage may be required to pull it towards the back plate. Once the substrate has been pulled to be close to and/or in contact with the back plate, a much smaller voltage is required to maintain the substrate close to the back plate. The electrostatic energy is applied at a high level consistent with retaining the substrate 610 on the back plate during transport into the chamber, but can be reduced once the substrate is close to the back plate. Thus, when the carrier and substrate are in the vacuum chamber, the voltage can be reduced to a lower value that can be supported in a vacuum without causing an electric arc between the grounded front surface of the substrate and the voltage on the back plate.

Conclusion

It will be understood that many additional changes in the details, materials, steps and arrangement of parts, which have been herein described and illustrated to explain the nature of the invention, may be made by those skilled in the art within the principle and scope of the invention as expressed in the appended claims. FIG. 3 is a diagram depicting movement of a substrate through a moving deposition chamber in a thin film photovoltaic fabrication process.

1. A method for fabricating thin film semiconductor devices comprising:
mounting a substrate so as to juxtapose the substrate against a back plate;
transporting the back plate with the substrate through a deposition chamber;
exposing the substrate to a deposition process in the deposition chamber; and
heating or cooling the substrate through the back plate during the deposition process.

2. The method of claim 1, comprising selecting, a material for the back plate is a material having a high value of thermal conductivity.

3. The method of claim 2, comprising selecting, the material having the thermal conductivity for use in the back plate from the group consisting of aluminum, copper and alumina.

4. The method of claim 1, wherein the deposition processes includes Plasma Enhanced Chemical Vapor Deposition (PECVD).

5. The method of claim 1, wherein the deposition processes includes an in-line Plasma Enhanced Chemical Vapor Deposition (PECVD) process, in which the transporting of the back plate with the substrate results in moving the substrate past a linearly configured PECVD deposition source.

6. The method of claim 1, further comprising positioning the substrate in a substantially vertical alignment, with the carrier and substrate transported in a substantially horizontal direction within the deposition chamber past a deposition source.

7. The method of claim 1, further comprising using at least one retention insert positionable at a perimeter region of the substrate, so as to retain the substrate in a juxtaposed position against the back plate.

8. The method of claim 1, further comprising using at least one retention insert positionable at a perimeter region of the substrate, so as to retain the substrate in a juxtaposed position against the back plate, and made of a material that closely matches a thermal expansion coefficient of the substrate.

9. The method of claim 1, comprising:
providing a pre-bowed configuration to the substrate;
positioning a convex side of the substrate toward the back plate; and
mounting the substrate by clamping the back plate against the substrate, thereby causing the back plate to engage the substrate, flatten the bow and establish thermal communication between the substrate and the back plate; wherein the back plate provides heat sinking of the substrate.

10. The method of claim 1, further comprising:
providing a vacuum between at least a portion of the substrate and the back plate, so as to retain the substrate in thermal communication with the back plate.

11. The method of claim 1, comprising:
establishing electrostatic attraction between the substrate and the backing plate.

12. The method of claim 1, comprising:
establishing electrostatic attraction between the substrate and the backing plate by applying a voltage differential between the substrate and the backing plate; and
decreasing the voltage differential once the substrate is pulled close to backing plate and when the carrier and substrate are at vacuum in the deposition chamber.

13. An apparatus for performing a fabrication process on a substrate, the apparatus comprising:
a substrate carrier, the substrate carrier including a back plate for juxtaposition against the substrate, the back plate having a heat spreading capability so as to provide temperature uniformity during a deposition process;
a vacuum deposition station containing a deposition apparatus; and
a transport mechanism capable of moving the substrate carrier past the deposition apparatus in a generally linear direction within the deposition station so as to perform the deposition process.

14. The apparatus of claim 13, wherein the deposition processes implements Plasma Enhanced Chemical Vapor Deposition (PECVD).

15. The apparatus of claim 13, wherein the deposition processes implements an in-line Plasma Enhanced Chemical Vapor Deposition (PECVD) process, in which the transporting of the back plate with the substrate results in moving the substrate past a linearly configured PECVD deposition source.

16. The apparatus of claim 13, wherein the transport mechanism positions the carrier and substrate in a substantially vertical alignment, and transports the carrier and substrate in a substantially horizontal direction within the deposition chamber past a deposition source.

17. The apparatus of claim 13, wherein the back plate includes a metal plane in thermal communication with the substrate.

18. The apparatus of claim 13, wherein the back plate includes a ceramic plane in thermal communication with the substrate.

19. The apparatus of claim 13, further comprising at least one retention insert positionable at a perimeter region of the substrate, and made of a material that closely matches a thermal expansion coefficient of the substrate.

20. The apparatus of claim 13, further comprising at least one retention insert positionable at a perimeter region of the substrate, and made of titanium or a material that closely matches a thermal expansion coefficient of the substrate in the manner of titanium.

21. The apparatus of claim 13, comprising:
a clamping arrangement supporting the substrate within the substrate carrier against the back plate, such that, in the case of the substrate including a pre-bowed configuration, with a convex side of the substrate facing the back plate, the clamping arrangement causes the back plate to engage the substrate, flatten the substrate against the back plate and establish thermal communication between the substrate and the back plate to cause the back plate to provide heat spreading to create a uniform temperature across the substrate.

22. The apparatus of claim 13, comprising:
the back plate configured with at least one vacuum cavity, so as to retain the substrate in thermal communication with the back plate.

23. The apparatus of claim 13, comprising an elastomeric seal capable of sealing the substrate is sealed against the back plate.

24. The apparatus of claim 13, comprising:
the back plate configured to establish electrostatic attraction between the substrate and the backing plate.

25. The apparatus of claim 24, comprising an insulating member providing electrical insulation between the substrate and an electrically charged portion of the back plate, while permitting said electrostatic attraction.
